(19) United States
(12) Patent Application Publication
(10) Pub. No.: US 2002/0155378 A1
(43) Pub. Date: Oct. 24, 2002

(54) Chemical amplifying type positive resist compositions

(76) Inventors: Yasunori Uetani, Osaka (JP); Hiroaki Fujishima, Osaka (JP); Kaoru Araki, Kyoto-shi (JP)

Correspondence Address: BIRCH STEWART KOLASCH & BIRCH, PO BOX 747, FALLS CHURCH, VA, 22040-0747, US

(21) Appl. No.: 10/075,342

(22) Filed: Feb. 15, 2002

(30) Foreign Application Priority Data
Feb. 19, 2001 (JP) 2001-041389

(51) Int. Cl. G03F 7/039

(52) U.S. Cl. 430/270.1; 430/945; 430/914

(57) ABSTRACT

A chemical amplifying type positive resist composition having resolution and sensitivity that are well balanced, undergoing a minimum of shrinkage due to the irradiation with electron rays of SEM, and comprising a resin that has a polymerization unit derived from an unsaturated monomer expressed by the following formula (1) and that itself is insoluble in an alkali but becomes alkali-soluble due to the action of an acid; and an acid generating agent:

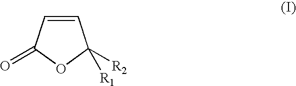

wherein R₁ and R₂ each independently represents hydrogen or a methyl group, is provided.

### BACKGROUND OF THE INVENTION

Field of the Invention

The present invention relates to a chemical amplifying type positive resist composition used in the fine processing of a semiconductor.

The fine processing of a semiconductor normally employs a lithography process using a resist composition. In the lithography, theoretically it is possible to increase the resolution higher as an exposure wavelength is shorter, as expressed by the Rayleigh diffraction limit formula. A light source for exposure in the lithography process used in the manufacture of semiconductors has come to have a shorter wavelength year by year, for instance, from G-ray with a wavelength of 436 nm, I-ray with a wavelength of 365 nm, to KrF eximer laser with a wavelength of 248 nm. As a light source for exposure of the next generation, ArF eximer laser with a wavelength of 193 nm has been considered most promising.

Since a lens used in the exposure with an ArF eximer laser has a shorter life as compared with the lenses for conventional exposure light sources, it is desirable that the lens is exposed to the ArF eximer laser beam for a period as shorter as possible. For this purpose, the sensitivity of a resist has to be improved. Therefore, using a catalytic effect of an acid generated by exposure, a so-called chemical amplifying type positive resist containing a resin having a group cleavable by the foregoing acid is employed.

It has been known that a resin having no aromatic ring in the structure so as to ensure a transmittance of the resist and having an alicyclic ring in place of an aromatic ring so as to be resistant against dry etching is preferably used in the resist for the exposure with the ArF eximer laser. As such resins, various types of resins have been known as mentioned by D. C. Hofer, Journal of Photopolymer Science and Technology, Vol. 9, No. 3, 387-398 (1996).

It has been also known that a copolymer consisting of alicyclic olefin unit and unsaturated dicarboxylic acid anhydride unit (T. I. Wallow et al., Proc. SPIE. Vol. 2724, pp.355-364 (1996)), a polymer having alicyclic lactone structural unit (JP2000-26446A), etc. may be used as resins used as resist component for the exposure with the ArF eximer laser. However, when a size of a resist pattern is measured by a scanning-type electron microscope (SEM), conventionally known resins used in a resist for the exposure with the ArF eximer laser tend to be damaged by the irradiation with electron beams of the SEM, thereby causing volume shrinkage, which leads to a problem of a significant decrease in size. This impairs the accuracy in the measurement of the resist size, thereby making it impossible to manufacture devices with stable performances.

An object of the present invention is to provide a chemical amplifying type positive resist composition that comprises a resin component and an acid generating agent, that is suitable for lithography employing an eximer laser of ArF, KrF, etc., that has well-balanced properties of resolution and sensitivity, and that undergoes a minimum of size shrinkage when being observed by SEM.

The inventors of the present invention have found that in the case where a resin containing a polymerization unit made of an unsaturated monomer having a certain specific structure is used as a part of polymerization units in a resin composing a chemical amplifying type positive resist composition, a resist composition can be obtained that exhibits well-balanced properties of resolution, profile, sensitivity, adhesivity, etc., and that undergoes a minimum of size shrinkage when being observed by SEM. Thus, the present invention was completed.

### SUMMARY OF THE INVENTION

The present invention provides a chemical amplifying type positive resist composition comprising a resin that has a polymerization unit derived from an unsaturated monomer expressed by the following formula (1) and that itself is insoluble in an alkali but becomes alkali-soluble due to the action of an acid; and an acid generating agent:

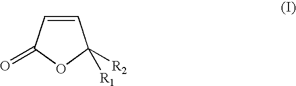

wherein R₁ and R₂ each independently represents hydrogen or a methyl group.

### DETAILED DESCRIPTION OF THE INVENTION

A resist composition of the present invention is characterized by comprising, as a resin component thereof, a resin having a polymerization unit derived from a monomer expressed by the aforementioned formula (1). Examples of the monomers expressed by the formula (1) specifically include the following chemical compounds.

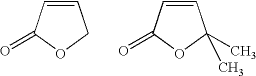

Furthermore, a resin in the present invention becomes soluble in an alkaline medium due to the action of an acid, though the resin itself is insoluble in an alkaline. The resin is used in a positive resist composition. The resin preferably includes a group that is cleavable by the action of an acid.

Examples of groups cleavable by the action of an acid include various types of esters of carboxylic acids. Examples of the esters include alkyl esters having 1 to 6 carbon atoms such as tert-butyl ester; acetal-type esters such as methoxy methyl ester, ethoxy methyl ester, 1-ethoxy ethyl ester, 1-isobthoxy ethyl ester, 1-isopropoxy ethyl ester, 1-ethoxy propyl ester, 1-(2-methoxyethoxy)ethyl ester, 1-(2-acetoxyethoxy)ethyl ester, 1-[2-(1-adamantyloxy)ethoxy]ethyl ester, 1-[2-(1-adamanthane-carbonyl-oxy)ethoxy]ethyl ester, tetrahydro-2-furyl ester, and tetrahydro-2-pyranyl ester; and alicyclic esters such as 2-alkyl-2-adamantyl, 1-(1-adamantyl)-1-alkylalkyl, and isobornyl ester.

Monomers for deriving polymerization units having such carboxylic acid esters may be acryl-based monomers such as methacrylic acid esters and acrylic acid esters, or alicyclic monomers linked with carboxylic acid ester groups such as norbornene carboxylic acid ester, tricyclodecene carboxylic acid ester, and tetracyclodecene carboxylic acid ester, or further alternatively, acrylic acids or methacrylic acids forming an ester bond with alicyclic groups of alicyclic carboxylic acid esters, as described in Iwasa et al., Journal of Photopolymer Science and Technology, Vol. 9, No. 3, pp. 447-456 (1996).

Among these monomers, those having bulky groups containing alicyclic groups such as 2-alkyl-2-adamantyl or 1-(1-adamantyl)-1-alkylalkyl, for example, are preferably used as groups cleavable by the action of an acid, since in such a case an excellent resolution can be obtained. Examples of monomers containing such bulky groups include 2-alkyl-2-adamantyl (meth)acrylates, 1-(1-adamantyl)-1-alkylalkyl (meth)acrylates, 2-alkyl-2-adamantyl 5-norbornen-2-carboxylates, 1-(1-adamantyl)-1-alkylalkyl 5-norbornen-2-carboxylates, etc.

Particularly, 2-alkyl-2-adamantyl (meth)acrylates are preferably used as monomers, since in such a case an excellent resolution can be obtained. Typical examples of such 2-alkyl-2-adamantyl (meth)acrylates include 2-methyl-2-adamantyl acrylate, 2-methyl-2-adamantyl methacrylate, 2-ethyl-2-adamantyl acrylate, 2-ethyl-2-adamantyl methacrylate, 2-n-butyl-2-adamantyl acrylate, etc.

Among these, 2-ethyl-2-adamantyl (meth)acrylate is particularly preferably used, since in this case the sensitivity and the heat resistance are well balanced. Another monomer having a group cleavable by the action of an acid may be used in combination as required.

The resin used in the present invention may additionally have polymerization units derived from monomers having no group cleavable by the action of an acid. Examples of such monomers include (meth)acrylic acid esters, alicyclic olefins, unsaturated dicarboxylic acid anhydrides, (meth)acrylonitrile, etc. Specifically, the following compounds are included:

3-hydroxy-1-adamantyl acrylate;

3-hydroxy-1-adamantyl methacrylate;

3,5-dihydroxy-1-adamantyl acrylate;

3,5-dihydroxy-1-adamantyl methacrylate;

α-acryloyloxy-γ-butyrolactone;

α-methacryloyloxy-γ-butyrolactone;

β-acryloyloxy-γ-butyrolactone;

β-methacryloyloxy-γ-butyrolactone;

5-acryloyloxy-2,6-norbornane carbolactone;

5-methacryloyloxy-2,6-norbornane carbolactone;

2-norbornen;

2-hydroxy-5-norbornen;

5-norbornen-2-carboxylate;

methyl 5-norbornen-2-carboxylate;

5-norbornen-2-carboxylate-t-butyl

1-cyclohexyl-1-methylethyl 5-norbornen-2-carboxylate;

1-(4-methylcyclohexyl)-1-methylethyl

5-norbornen-2-carboxylate;

1-(4-hydroxycyclohexyl)-1-methylethyl

5-norbornen-2-carboxylate;

1-methyl-1-(4-oxocyclohexyl)ethyl

5-norbornen-2-carboxylate;

1-(1-adamantyl)-1-methylethyl 5-norbornen-2-carboxylate;

1-methylcyclohexyl 5-norbornen-2-carboxylate;

2-methyl-2-adamantyl 5-norbornen-2-carboxylate;

2-ethyl-2-adamantyl 5-norbornen-2-carboxylate;

2-hydroxy-1-ethyl 5-norbornen-2-carboxylate;

5-norbornen-2-methanol;

5-norbornen-2,3-dicarboxylic acid anhydride;

etc.

maleic anhydride;

itaconic anhydride

A resin used in the present invention varies depending on the type of rays used in the exposure for patterning, the types of other polymerization units contained as required, etc., but it is preferably obtained by polymerizing 5 to 50 mol % of a monomer expressed by the formula (1) and 10 to 80 mol % of a monomer having a group cleavable by an acid, in combination with any other monomers as required.

The copolymerization can be carried out by a normal method. For example, a copolymer resin specified in the present invention can be obtained by dissolving the required monomers in an organic solvent and polymerizing the same in the presence of a polymerization initiator like an azo compound such as 2,2′-azo-bisisobutyronitrile or dimethyl 2,2′azobis(2-methylpropionate). After the reaction, it is advantageous to purify the same by reprecipitation.

The acid generating agent, another component of the resist composition, is a substance which is decomposed to generate an acid by applying a radiation such as a light, an electron beam or the like on the substance itself or on a resist composition containing the substance. The acid generated from the acid generating agent acts on said resin resulting in cleavage of the group cleavable by the action of an acid existing in the resin.

Such acid generating agents, for example, include other onium salt compounds, organno-halogen compound, sulfone compounds, sulfonate compounds, and the like.

Specific examples thereof include:

diphenyliodonium trifluoromethanesulfonate,

4-methoxyphenylphenyliodonium hexafluoroantimonate,

4-mthoxyphenylphenyliodonium trifluoromethanesulfonate,

bis(4-tert-butylphenyl)iodonium tetrafluoroborate,

bis(4-tert-butylphenyl)iodonium hexafluorophosphate,

bis(4-tert-butylphenyl)iodonium hexafluoroantimonate,

bis(4-tert-butylphenyl)iodonium trifluoromethanesulfonate,

triphenylsulfonium hexafluorophosphate,

triphenylsulfonium hexafluoroantimonate,

triphenylsulfonium trifluoromethanesulfonate,

4-methoxyphenyldiphenylsulfonium hexafluoroantimonate,

4-methoxyphenyldiphenylsulfonium trifluoromethanesulfonate,

p-tolyldiphenylsulfonium trifluoromethanesulfonate,

p-tolyldiphenylsulfonium perfluorooctanesulfonate,

p-tolyldiphenylsulfonium perfluorooctanesulfonate,

2,4,6-trimethylphenyldiphenylsulfonium trifluoromethanesulfonate,

4-tert-butylphenyldiphenylsulfonium trifluoromethanesulfonate,

4-phenylthiophenyldiphenylsulfonium hexafluorophosphate,

4-phenylthiophenyldiphenylsulfonium hexafluoroantimonate,

1-(2-naphthoylmethyl)thiolanium hexafluoroantimonate,

1-(2-naphthoylmethyl) thiolanium trifluoromethanesulfonate,

4-hydroxy-1-naphthyldimethylsulfonium hexafluoroantimonate,

4-hydroxy-1-naphthyldimethylsulfonium trifluoromethanesulfonate,

cyclohexylmethyl(2-oxocyclohexyl)sulfonium trifluoromethanesulfonate,

cyclohexylmethyl(2-oxocyclohexyl)sulfonium perfluorobutanesulfonate,

cyclohexylmethyl(2-oxocyclohexyl)sulfonium perfluorooctanesulfonate,

2-methyl-4,6-bis(trichloromethyl)-1,3,5-triazine,

2,4,6-tris(trichloromethyl)-1,3,5-triazine,

2-phenyl-4,6-bis(trichloromethyl)-1,3,5-triazine,

2-(4-chlorophenyl)-4,6-bis(trichloromethyl)-1,3,5-triazine,

2-(4-methoxyphenyl)-4,6-bis(trichloromethyl)-1,3,5-triazine,

2-(4-methoxy-1-naphthyl)-4,6-bis(trichloromethyl)-1,3,5-triazine,

2-(benzo[d][1,3]dioxolane-5-yl)-4,6-bis(trichloromethyl)-1,3,5-triazine,

2-(4-methoxystyryl)-4,6-bis(trichloromethyl)-1,3,5-triazine,

2-(3,4,5-trimethoxystyryl)-4,6-bis(trichloromethyl)-1,3,5-triazine,

2-(2,4-dimethoxystyryl)-4,6-bis(trichloromethyl)-1,3,5-triazine.

2-(2-methoxystyryl)-4,6-bis(trichloromethyl)-1,3,5-triazine,

2-(4-butoxystyryl)-4,6-bis(trichloromethyl)-1,3,5-triazine,

2-(4-pentyloxystyryl)-4,6-bis(trichloromethyl)-1,3,5-triazine,

diphenyl disulfone,

di-p-tolyl disulfone,

bis(phenylsulfonyl)diazomethane,

bis(4-chlorophenylsulfonyl)diazomethane,

bis p-tolylsulfonyl)diazomethane,

bis(4-tert-butylphenylsulfonyl)diazomethane,

bis(2,4-xylylsulfonyl)diazomethane,

bis(cyclohexylsulfonyl)diazomethane,

(benzoyl)(phenylsulfonyl)diazomethane,

1-benzoyl-1-phenylmethyl p-toluenesulfonate (so-called benzointosylate),

2-benzoyl-2-hydroxy-2-phenylethyl p-toluenesulfonate (so-called α-methylolbenzointosylate)

1,2,3-benzenetriyl trimethanesulfonate,

2,6-dinitrobenzyl p-toluenesulfonate,

2-nitrobenzyl p-toluenesulfonate,

4-nitrobenzyl p-toluenesulfonate,

N-(phenylsulfonyloxy)succinimide,

N-(trifluoromethylsulfonyloxy)succinimide,

N-(trifluoromethylsulfonyloxy)phthalimide,

N-(trifluoromethylsulfonyloxy)-5-norbornene-2,3-dicarboxyimide,

N-(trifluoromethylsulfonyloxy)naphthalimide,

N-(10-camphorsulfonyloxy)naphthalimide, and the like.

It is also known that, generally in a chemical amplifying type positive resist composition, performance deterioration due to the deactivation of an acid associated with leaving after exposure can be reduced by adding basic compounds, especially basic nitrogen-containing organic compounds such as amines as quenchers. It is also preferable in the present invention that such basic compounds are added. Concrete examples of the basic compounds to be used as quenchers include the ones represented by the following formulae:

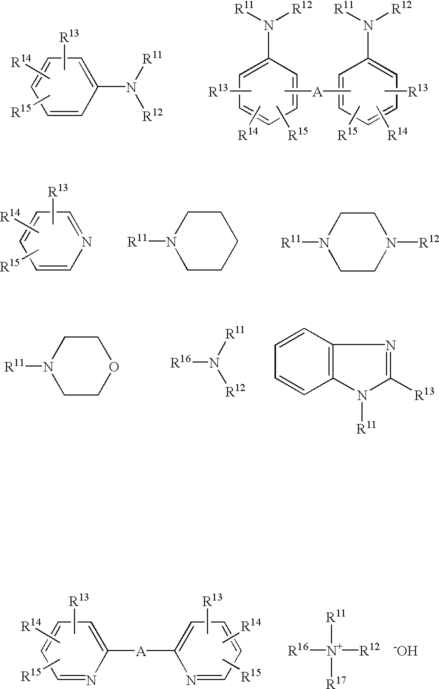

wherein R¹¹, R¹² and R¹⁷ represent, independently each other, hydrogen, cycloalkyl, aryl or alkyl which may be optionally substituted with a hydroxyl, amino which may be optionally substituted with alkyl having 1 to 6 carbon atoms, or alkoxy having 1 to 6 carbon atoms: R¹³, R¹⁴ and R¹⁵, which are same or different from each other, represent hydrogen, cycloalkyl, aryl, alkoxy or alkyl which may be optionally substituted with a hydroxyl, amino which may be optionally substitiuted with alkyl having 1 to 6 carbon atoms, or alkoxy having 1 to 6 carbon atoms; R¹⁶ represents cycloalkyl or alkyl which may be optionally substituted with a hydroxyl, amino which may be optionally substitiuted with alkyl having 1 to 6 carbon atoms, or alkoxy having 1 to 6 carbon atoms; A represents alkylene, carbonyl, imino, sulfide or disulfide. The alkyl represented by R¹¹ to R¹⁷ and alkoxy represented by R¹³ to R¹⁵ may have about 1 to 6 carbon atoms. The cycloalkyl represented by R¹¹ to R¹⁷ may have about 5 to 10 carbon atoms and the aryl represented by R¹¹ to R¹⁵ and R¹⁷ may have about 6 to 10 carbon atoms. The alkylene represented by A may have about 1 to 6 carbon atoms and may be straight-chained or branched.

The resist composition of the present invention preferably contains the resin in an amount of 80 to 99.9% by weight, and the acid generating agent in an amount of 0.1 to 20% by weight based on the total weight of the resin and the acid generating agent. When a basic compound is used as a quencher, it is preferably contained in an amount in the range of 0.001 to 0.1 part by weight, more preferably 0.01 to 0.3 part by weight per 100 parts by weight of the resin. The composition may also contain, if required, a small amount of various additives such as sensitizers, dissolution inhibitors, resins other than the above resin, surfactants, stabilizers, and dyes so far as the objects of the present invention is not harmed.

The resist composition of the present invention generally becomes a resist solution in the state in which the above-described components are dissolved in a solvent to be applied on a substrate such as a silicon wafer. The solvent herein used may be one which dissolves each component, has an appropriate drying rate, and provides a uniform and smooth coating after evaporation of the solvent, and can be one which is generally used in this field.

Examples thereof include glycol ether esters such as ethylcellosolve acetate, methylcellosolve acetate, and propylene glycol monomethyl ether acetate; esters such as ethyl lactate, butyl acetate, amyl acetate, and ethyl pyruvate; ketones such as acetone, methyl isobutyl ketone, 2-heptanone, and cyclohexanone; and cyclic esters such as γ-butyrolactone. These solvents can be used alone or in combination of two or more thereof.

The resist film applied on a substrate, and dried is subjected to an exposure treatment for patterning. Then, after a heat-treatment for promoting a protecting deblocking reaction, development by an alkali developer is conducted. The alkali developer herein used can be various kinds of alkaline aqueous solutions used in this field. In general, an aqueous solution of tetramethylammoniumhydroxide or (2-hydroxyethyl)trimethylammoniumhydroxide (so-called colline) is often used.

The present invention will be described in more detail by way of examples, which should not be construed as limiting the scope of the present invention. All parts in examples are by weight unless otherwise stated. The weight-average molecular weight is a value determined from gel permeation chromatography using polystyrene as a reference standard.

### RESIN SYNTHESIS EXAMPLE 1

### Synthesis of Resin A1

2-ethyl-2-adamantyl-methacrylate, 3-hydroxy-1-adamantyl acrylate, 2-norbornen, and 2(5H)franone were mixed at a ratio of 2:2:3:3 (20.0 g:17.9 g:11.4 g:10.2 g), and 2-ethylhexyl 3-mercaptopropionate, equivalent to 3 mol % of all the monomers of the foregoing mixture, was added thereto. Then, methyl isobutyl ketone, equivalent to 2 times all the monomers by weight, was added thereto so as to obtain a solution. Furthermore, azo-bisisobutyronitrile, equivalent to 1 mol % of all the monomers, was added thereto as an initiator. Thereafter, it was heated to 80° C., and was stirred for 15 hours. After the reaction mass was cooled, an operation of precipitation with a massive amount of methanol was carried out three times for purification, and a copolymer having a weight average molecular weight of approximately 6000 was obtained. This copolymer is hereinafter referred to as resin A1.

### RESIN SYNTHESIS EXAMPLE 2

### Synthesis of Resin AX

2-ethyl-2-adamantyl-methacrylate, 3-hydroxy-1-adamantyl methacrylate, and α-methacryloyloxy-γ-butyrolactone were mixed at a ratio of 2:1:1 (20.0 g:9.5 g:6.8 g), and methyl isobutyl ketone, equivalent to 2 times all the monomers by weight, was added thereto so as to obtain a solution. Furthermore, azobis isobutyronitrile, equivalent to 2 mol % of all the monomers, was added thereto as an initiator. Thereafter, it was heated to 85° C., and was stirred for 5 hours. After the reaction mass was cooled, an operation of precipitation with a massive amount of methanol was carried out three times for purification, and a copolymer having a weight average molecular weight of approximately 10000 was obtained. This copolymer is hereinafter referred to as resin AX.

Next, resist compositions were prepared using acid generating agents and quenchers shown below in addition to the respective resins obtained in the foregoing resin synthesis examples. The results of evaluation of the same are shown below.

### EXAMPLE 1 AND COMPARATIVE EXAMPLE 1

The following components were mixed and dissolved, and faltered through a fluorine resin filter having a pore diameter of 0.2 μm to prepare a resin solution.

| | | |
|---|---|---|
| Resin (as to type, see Table 1) | 10 | parts |
| Acid generating agent: p-tolyldiphenyl sulfonium | 0.2 | part |
| perfluorooctane sulfonate | | |
| Quencher: 2,6-diisopropile aniline | 0.0075 | parts |

Solvent:
In Example 1,

| | | |
|---|---|---|
| Propylene glycol monomethyl ether acetate | 9 | parts |
| γ-butyrolactone | 3 | parts |
| 2-heptanone | 48 | parts |

In Comparative Example 1,

| | | |
|---|---|---|
| Propylene glycol monomethyl ether acetate | 57 | parts |
| γ-butyrolactone | 3 | parts |

An organic anti-reflective coating composition, ARC-25-8, manufactured by Brewer was coated on a silicon wafer and was baked at 215° C. for 60 seconds, so that a 780 Å-thick organic anti-reflective coating was formed. The resist solution prepared as described above was applied thereon by spin coating so as to have a thickness of 0.39 μm. After the application of the resist, it was prebaked at temperatures shown in the column “PB” in Table 1 for 60 seconds on a direct hot plate. The wafer on which a resist film was thus provide was exposed using an ArF eximer stepper (“NSR ArF” manufactured by NICON, NAT=0.55, σ=0.6), so that a line-and-space pattern was formed by varying an exposure light quantity stepwisely.

After the exposure, it was subjected to post-exposure baking on a hot plate at a temperature shown in the column “PEB” in Table 1 for 60 seconds, and further, subjected to paddle development for 60 seconds by using 2.38 wt % aqueous solution of tetramethylammonium hydroxide.

The line-and-space pattern on the organic anti-reflective film substrate after the development was observed with a scanning-type electron microscope, and effective sensitivity, resolution, and variation in sizes due to SEM were measured by the following method. The results are shown in Table 1.

Effective sensitivity: expressed by exposure amount causing line-and-space pattern of 0.18 μm to be 1:1.

Resolution: expressed by a minimum size of a line-and-space pattern resolved with the light exposure of the effective sensitivity.

Variation in size due to SEM: A line pattern of 0.22 μm was measured with the light exposure of the effective sensitivity. In one portion, length measurement under conditions of an acceleration voltage of 800 V and a current of 12 pA by a normal method was carried out every 10 seconds repeatedly using a length-measuring SEM (KLA-8100XP) manufactured by KLA-Tencor Corporation. The variation in size due to SEM was expressed by a difference between a value measured in the first measurement and a value measured in the 20th measurement.

TABLE 1

| | | | | Effective | Resolu- | SEM |
|---|---|---|---|---|---|---|
| | | PB | PEB | Sensitivity | tion | Shrinkage |
| Example No. | Resin | ° C. | ° C. | (mJ/cm²) | (μm) | (μm) |
| Example 1 | A1 | 120 | 120 | 12 | 0.15 | 0.006 |
| Comparative | AX | 130 | 130 | 22 | 0.15 | 0.01 |
| Example 1 | | | | | | |

As seen in Table 1, the resist of Example 1 had sensitivity and resolution that are excellently balanced, and underwent smaller shrinkage due to the irradiation with electron beams of SEM.

The chemical amplifying type positive resist composition of the present invention has resolution and sensitivity that are well balanced, and undergoes a minimum of shrinkage due to the irradiation with electron rays of SEM. Therefore, the composition is suitable for the exposure in which KrF eximer laser or ArF eximer laser. Hence it provides a resist pattern with high performance, and ensures size measurement with high accuracy.

What is claimed is;

1. A chemical amplifying type positive resist composition comprising a resin that has a polymerization unit derived from an unsaturated monomer expressed by the following formula (1) and that itself is insoluble in an alkali but becomes alkali-soluble due to the action of an acid; and an acid generating agent: 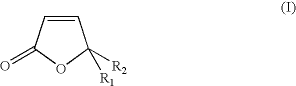
wherein R₁ and R₂ each independently represents hydrogen or a methyl group.

2. The chemical amplifying type positive resist composition according to claim 1 which comprises the resin in an amount of 80 to 99.9 by weight, and the acid generating agent in an amount of 0.1 to 20% by weight based on the total weight of the resin and the acid generating agent.

3. The chemical amplifying type positive resist composition according to claim 1 wherein the resin contains the polymerization unit derived from a monomer expressed by the formula (1) in an amount of 5 to 50 mol %.

4. The chemical amplifying type positive resist composition according to claim 1 wherein the resin contains a polymerization unit having a group cleavable by the action of an acid.

5. The chemical amplifying type positive resist composition according to claim 4 wherein the polymerization unit having a group cleavable by the action of an acid is derived from a 2-alkyl-2-adamantyl (meth)acrylate.

6. The chemical amplifying type positive resist composition according to claim 5 wherein the polymerization unit derived from a 2-alkyl-2-adamantyl (meth)acrylate is derived from 2-ethyl-2-adamantyl acrylate or 2-ethyl-2-adamantyl methacrylate.

7. The chemical amplifying type positive resist composition according to claim 1 which further comprises a basic compound as a quencher.

8. The chemical amplifying type positive resist composition according to claim 7 wherein the amount of the basic compound is in the range of 0.001 to 0.1 part by weight per 100 parts by weight of the resin.
